(19) United States
(12) Patent Application Publication
(10) Pub. No.: US 2026/0018541 A1
(43) Pub. Date: Jan. 15, 2026

(54) LAYOUT SCHEME FOR METAL-INSULATOR-METAL CAPACITORS

(71) Applicant: SKYWORKS SOLUTIONS, INC., Irvine, CA (US)

(72) Inventors: Peihua Ye, Irvine, CA (US); Thomas Obkircher, Santa Ana, CA (US)

(21) Appl. No.: 19/263,659

(22) Filed: Jul. 9, 2025

Related U.S. Application Data
(60) Provisional application No. 63/669,412, filed on Jul. 10, 2024.

(51) Int. Cl. H01L 23/66; H01L 23/522; H03H 9/02; H04B 1/00; H04B 1/40; H10D 1/68

(52) U.S. Cl. CPC H01L 23/66; H04B 1/0057; H04B 1/40; H10D 1/68; H01L 23/5223; H01L 2223/6677; H01L 2223/6688; H03H 9/02834; H03H 9/02858

(57) ABSTRACT

Aspects and embodiments disclosed herein include a semiconductor device comprising a metal-insulator-metal capacitor having a capacitance. The metal-insulator-metal capacitor comprises a plurality of metal-insulator-metal capacitors coupled in parallel, each metal-insulator-metal capacitor of the plurality of metal-insulator-metal capacitors having a top plate, a bottom plate, and a corresponding capacitance, and a plurality of bottom contacts, at least one of the plurality of bottom contacts arranged between a pair of directly adjacent metal-insulator-metal capacitors of the plurality of metal-insulator-metal capacitors. Also disclosed are antennaplexers, electronic device modules, and electronic devices including aspects and embodiments of the semiconductor device.

### CROSS-REFERENCE TO RELATED APPLICATIONS

This application claims priority under 35 U.S.C. § 119(e) to U.S. Provisional Patent Application Ser. No. 63/669,412, titled “LAYOUT SCHEME FOR METAL-INSULATOR-METAL CAPACITORS,” filed Jul. 10, 2024, the entire content of which is incorporated herein by reference for all purposes.

### BACKGROUND

### Field

The present disclosure relates generally to improved layout schemes for metal-insulator-metal (MIM) capacitors (CAPs) enabling an improved quality factor (Q), in particular for front-end modules (FEMs) including antennaplexers to propagate a signal to a particular transmit (Tx) and/or receive (Rx) path. More generally, aspects of the present disclosure relate to systems enabling improved performance due to the use of MIM CAPs having an improved Q.

### Description of the Related Technology

Communication systems can be used for transmitting and/or receiving signals of a wide range of frequencies. For example, a RF communication system can be used to wirelessly communicate RF signals in a frequency range of about 30 kHz to 300 GHz, such as in the range of about 450 MHz to about 7.125 GHz for certain communications standards.

Front-end modules (FEMs) are used for signal reception (Rx) and transmission (Tx). In certain implementations, communications systems can be simultaneously and/or multiply connected to one or more networks of the same and/or of different generations and at same, similar, or different bands and transmit and/or receive a plurality of signals simultaneously.

When a system is transmitting, a signal is delivered to a FEM, which amplifies the signal with possibly minimal distortion and drives it to an antenna to be transmitted to a remote client. Conversely when the radio system is receiving, a possibly weak signal is received from a remote client and amplified before being delivered to the system for processing.

A FEM includes antennaplexers to propagate the signal to a particular Tx and/or Rx path. Antennaplexers include resonators and filters which can include one or more capacitors throughout the Tx and/or Rx path to improve performance of signal propagation.

### SUMMARY

The systems, methods, and devices of this disclosure each have several aspects, no single one of which is solely responsible for the desirable attributes disclosed herein.

Aspects and embodiments disclosed herein include systems enabling improved performance of signal propagation across transmit and/or receive paths due to the use of metal-insulator-metal capacitors having an improved Q because of, at least in part, advantageous layout schemes of the metal-insulator-metal capacitors.

In accordance with one aspect, there is provided a semiconductor device comprising a metal-insulator-metal (MIM) capacitor (CAP) having a capacitance C. The MIM CAP comprises a plurality of N MIM CAPs coupled in parallel, each MIM CAP of the N MIM CAPs having a top plate, a bottom plate, and a corresponding capacitance Cᵢ, and a plurality of bottom contacts, at least one of the plurality of bottom contacts arranged between a pair of directly adjacent MIM CAPs of the plurality of N MIM CAPs.

In some embodiments, the bottom plates of at least two MIM CAPs of the plurality of N MIM CAPs are arranged in a first layer of the at least two MIM CAPs.

In some embodiments, each bottom plate of each MIM CAP of the plurality of N MIM CAPs is arranged in the first layer of each MIM CAP of the plurality of N MIM CAPs.

In some embodiments, each bottom plate of each MIM CAP of the plurality of N MIM CAPs has a rectangular shape, in particular a square shape.

In some embodiments, each of the bottom plates of the plurality of N MIM CAPs has a rectangular shape, in particular a square shape.

In some embodiments, the plurality of bottom contacts comprise a bottom contact between each pair of directly adjacent MIM CAPs of the plurality of N MIM CAPs.

In some embodiments, N is equal to 2, 4, 6, 8, or 10.

In some embodiments, at least two MIM CAPs of the plurality of N MIM CAPs have a same capacitance Cᵢ and/or at least at least two MIM CAPs of the plurality of N MIM CAPs have a different capacitance Cᵢ.

In some embodiments, each MIM CAP of the plurality of N MIM CAPs has the same capacitance Cᵢ.

In some embodiments, each MIM CAP of the plurality of N MIM CAPs is arranged between a metal 2 and a metal 3 layer and has a capacitance of 2 fF/μm².

In accordance with another aspect, there is provided an antennaplexer. The antennaplexer comprises a first signal path between an antenna port and a first output port, the first signal path including a first resonator in series with a first metal-insulator-metal (MIM) capacitor (CAP) having a capacitance C, the first MIM CAP including a plurality of N MIM CAPs coupled in parallel, each MIM CAP of the N MIM CAPs having a top plate, a bottom plate, and a corresponding capacitance, and a plurality of bottom contacts, at least one of the plurality of bottom contacts arranged between a pair of directly adjacent MIM CAPs of the plurality of N MIM CAPs, a first shunt path connected to the first signal path between the first resonator and the first output port, and a second signal path between the antenna port and a second output port, the first signal path configured to transmit signals of a first frequency band and the second signal path configured to transmit signals of a second frequency band that differs from the first frequency band.

In some embodiments, the first MIM CAP substitutes for a second resonator.

In some embodiments, the first shunt path includes a stacked resonator including a second resonator in series with a third resonator.

In some embodiments, the first shunt path further includes a second MIM CAP in series with the stacked resonator.

In some embodiments, the second MIM CAP substitutes for a fourth resonator in series with the stacked resonator.

In some embodiments, the first signal path includes a second resonator between the first shunt path and the first output port.

In some embodiments, the antennaplexer further comprises a second shunt path connected to the first signal path between a node where the first shunt path connects to the first signal path and the first output port.

In some embodiments, the second signal path includes an inductor-capacitor network without a resonator.

In some embodiments, the first resonator is an acoustic wave resonator.

In some embodiments, the acoustic wave resonator is a temperature compensated surface acoustic wave device.

In some embodiments, the second signal path includes a stacked resonator including a second resonator in series with a third resonator.

In some embodiments, the antennaplexer further comprises a second shunt path connected to the second signal path between the stacked resonator and the second output port.

In some embodiments, the second shunt path includes a third resonator in series with an inductor.

In some embodiments, the antennaplexer further comprises a third shunt path connected to the second signal path between a node where the second shunt path connects to the second signal path and the second output port.

In some embodiments, the first frequency band corresponds to a cellular communication band and the second frequency band corresponds to a global positioning system band.

In accordance with another aspect, there is provided a front-end module. The front end module comprises a power amplifier module configured to amplify one or more radio frequency signals, and an antennaplexer including a first signal path, a shunt path, and a second signal path, the first signal path between an antenna port and a first output port, and including a first resonator in series with a first metal-insulator-metal (MIM) capacitor (CAP) having a capacitance C, the first MIM CAP including a plurality of N MIM CAPs coupled in parallel, each MIM CAP of the N MIM CAPs having a top plate, a bottom plate, and a corresponding capacitance, and a plurality of bottom contacts, at least one of the plurality of bottom contacts arranged between a pair of directly adjacent MIM CAPs of the plurality of N MIM CAPs, the first output port in communication with the power amplifier module, the shunt path between the first resonator and the first output port, and the second signal path between the antenna port and a second output port, the first signal path configured to transmit signals of a first frequency band and the second signal path configured to transmit signals of a second frequency band.

In some embodiments, the first MIM CAP substitutes for a second resonator.

In some embodiments, the shunt path includes a stacked resonator including a second resonator in series with a third resonator.

In accordance with another aspect, there is provided a mobile device. The mobile device comprises an antenna configured to transmit and receive radio frequency signals, a transceiver, and an antennaplexer between the antenna and the transceiver, the antennaplexer including a first signal path, a shunt path, and a second signal path, the first signal path between an antenna port connected to the antenna and a first output port connected to the transceiver, and the first signal path including a resonator in series with a first metal-insulator-metal (MIM) capacitor (CAP) having a capacitance C, the first MIM CAP including a plurality of N MIM CAPs coupled in parallel, each MIM CAP of the N MIM CAPs having a top plate, a bottom plate, and a corresponding capacitance, and a plurality of bottom contacts, at least one of the plurality of bottom contacts arranged between a pair of directly adjacent MIM CAPs of the plurality of N MIM CAPs, the shunt path between the resonator and the first output port, and the second signal path between the antenna port and a second output port, the first signal path configured to transmit signals of a first frequency band and the second signal path configured to transmit signals of a second frequency band.

### BRIEF DESCRIPTION OF THE DRAWINGS

Embodiments of this disclosure will be described, by way of non-limiting example, with reference to the accompanying drawings.

FIG. 1 is a schematic diagram of one example of a communication network.

FIG. 2A is a schematic diagram of one example of a communication link using carrier aggregation.

FIG. 2B illustrates various examples of uplink carrier aggregation for the communication link of FIG. 2A.

FIG. 2C illustrates various examples of downlink carrier aggregation for the communication link of FIG. 2A.

FIG. 3 illustrates a block diagram of an aspect of a wireless device.

FIG. 4 illustrates a block diagram of a portion of a wireless device with an antennaplexer.

FIG. 5 illustrates a block diagram of an antennaplexer in accordance with certain aspects of the present disclosure.

FIG. 6 illustrates a circuit diagram of an antennaplexer in accordance with certain aspects of the present disclosure.

FIG. 7 illustrates a circuit diagram of an alternative antennaplexer in accordance with certain aspects of the present disclosure.

FIG. 8 is a cross-sectional diagram of a temperature compensated surface acoustic wave (SAW) resonator according to an embodiment.

FIG. 9A illustrates a top view on a conventional MIM CAP and a corresponding equivalent circuit diagram for the MIM CAP having a capacitance C.

FIG. 9B illustrates a top view on an exemplary MIM CAP according to an exemplary embodiment and a corresponding circuit diagram for a part of the MIM CAP having a capacitance C/4 of the capacitance C of the conventional MIM CAP of FIG. 9A.

FIG. 10 illustrates a cross-section of an exemplary MIM CAP according to an embodiment and a corresponding circuit diagram for parts of the MIM CAP, each part having a capacitance C/4 of the capacitance C of the conventional MIM CAP of FIG. 9A.

FIG. 11A and FIG. 11B illustrate the performance of the conventional MIM CAP of FIG. 9A (dashed lines) and the performance of the exemplary MIM CAP of FIG. 9B (solid lines) as a function of frequency.

### DETAILED DESCRIPTION

In the following various specific embodiments are described. However, the innovations presented herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

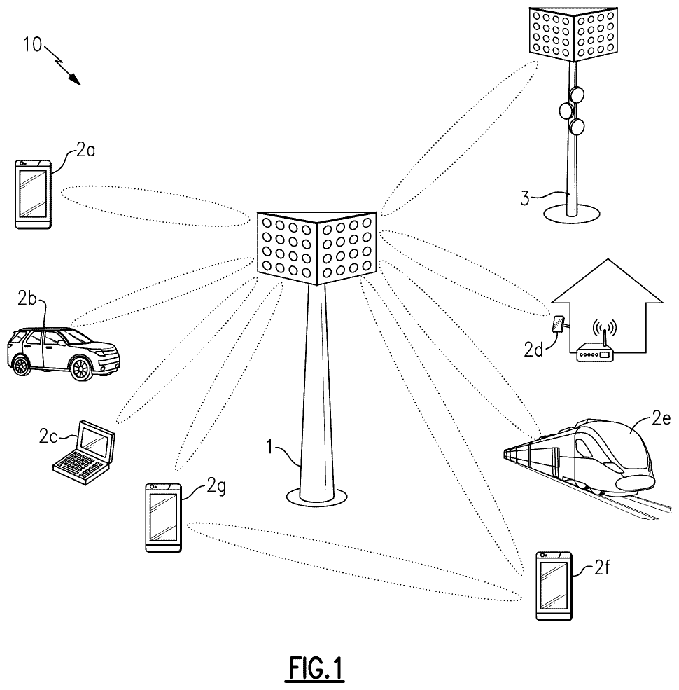

FIG. 1 is a schematic diagram of one example of a communication network 10. The communication network 10 includes a macro cell base station 1, a small cell base station 3, and various examples of user equipment (UE), including a first mobile device 2a, a wireless-connected car 2b, a laptop 2c, a stationary wireless device 2d, a wireless-connected train 2e, a second mobile device 2f, and a third mobile device 2g.

Although specific examples of base stations and user equipment are illustrated in FIG. 1, a communication network can include base stations and user equipment of a wide variety of types and/or numbers.

For instance, in the example shown, the communication network 10 includes the macro cell base station 1 and the small cell base station 3. The small cell base station 3 can operate with relatively lower power, shorter range, and/or with fewer concurrent users relative to the macro cell base station 1. The small cell base station 3 can also be referred to as a femtocell, a picocell, or a microcell. Although the communication network 10 is illustrated as including two base stations, the communication network 10 can be implemented to include more or fewer base stations and/or base stations of other types.

Although various examples of user equipment are shown, the teachings herein are applicable to a wide variety of user equipment, including, but not limited to, mobile phones, tablets, laptops, IoT devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 10 of FIG. 1 supports communications using a variety of cellular technologies, including, for example, fourth generation (4G) Long Term Evolution (LTE) and fifth generation (5G) New Radio (NR). In certain implementations, the communication network 10 is further adapted to provide a wireless local area network (WLAN). Although various examples of communication technologies have been provided, the communication network 10 can be adapted to support a wide variety of communication technologies.

Various communication links of the communication network 10 have been depicted in FIG. 1. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, or Wi-Fi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed Wi-Fi frequencies).

As shown in FIG. 1, the communication links include not only communication links between UE and base stations, but also UE to UE communications and base station to base station communications. For example, the communication network 10 can be implemented to support self-fronthaul and/or self-backhaul (for instance, as between mobile device 2g and mobile device 2f).

The communication links can operate over a wide variety of frequencies. In certain implementations, communications are supported using 5G NR technology over one or more frequency bands that are less than 6 Gigahertz (GHz) and/or over one or more frequency bands that are greater than 6 GHz. For example, the communication links can serve Frequency Range 1 (FR1), Frequency Range 2 (FR2), or a combination thereof. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz.

Different users of the communication network 10 can share available network resources, such as available frequency spectrum, in a wide variety of ways.

In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 2 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 10 of FIG. 1 can be used to support a wide variety of advanced communication features, including, but not limited to, eMBB, uRLLC, and/or mMTC.

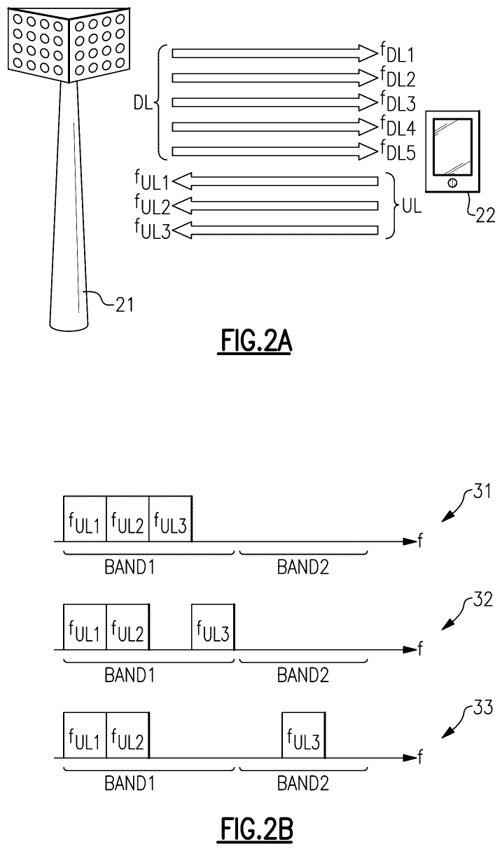

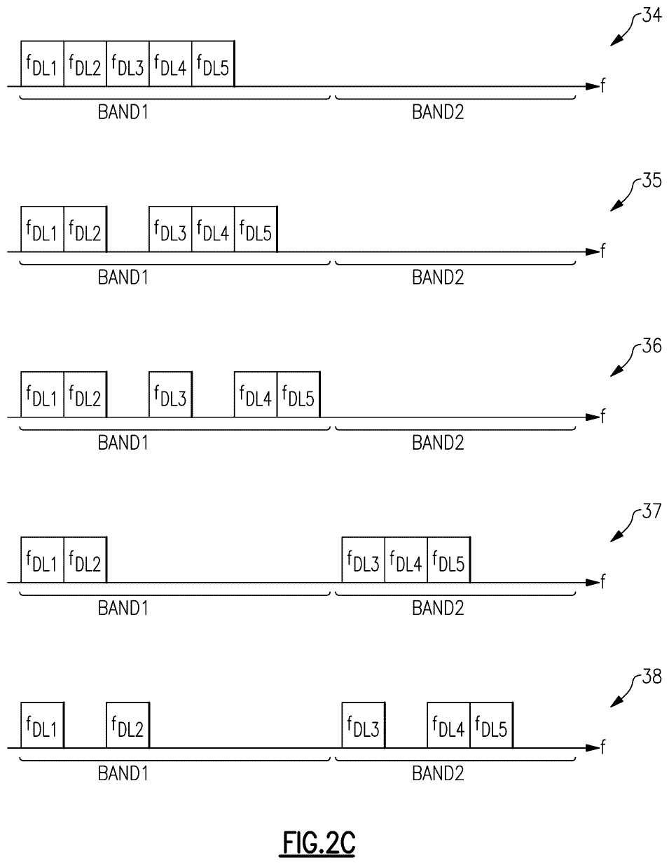

FIG. 2A is a schematic diagram of one example of a communication link using carrier aggregation. Carrier aggregation can be used to widen bandwidth of the communication link by supporting communications over multiple frequency carriers, thereby increasing user data rates and enhancing network capacity by utilizing fragmented spectrum allocations.

In the illustrated example, the communication link is provided between a base station 21 and a mobile device 22. As shown in FIG. 2A, the communications link includes a downlink channel used for RF communications from the base station 21 to the mobile device 22, and an uplink channel used for RF communications from the mobile device 22 to the base station 21.

Although FIG. 2A illustrates carrier aggregation in the context of FDD communications, carrier aggregation can also be used for TDD communications.

In certain implementations, a communication link can provide asymmetrical data rates for a downlink channel and an uplink channel. For example, a communication link can be used to support a relatively high downlink data rate to enable high speed streaming of multimedia content to a mobile device, while providing a relatively slower data rate for uploading data from the mobile device to the cloud.

In the illustrated example, the base station 21 and the mobile device 22 communicate via carrier aggregation, which can be used to selectively increase bandwidth of the communication link. Carrier aggregation includes contiguous aggregation, in which contiguous carriers within the same operating frequency band are aggregated. Carrier aggregation can also be non-contiguous, and can include carriers separated in frequency within a common band or in different bands.

In the example shown in FIG. 2A, the uplink channel includes three aggregated component carriers f_{UL1}, f_{UL2}, and f_{UL3}. Additionally, the downlink channel includes five aggregated component carriers f_{DL1}, f_{DL2}, f_{DL3}, f_{DL4}, and f_{DL5}. Although one example of component carrier aggregation is shown, more or fewer carriers can be aggregated for uplink and/or downlink. Moreover, a number of aggregated carriers can be varied over time to achieve desired uplink and downlink data rates.

For example, a number of aggregated carriers for uplink and/or downlink communications with respect to a particular mobile device can change over time. For example, the number of aggregated carriers can change as the device moves through the communication network and/or as network usage changes over time.

FIG. 2B illustrates various examples of uplink carrier aggregation for the communication link of FIG. 2A. FIG. 2B includes a first carrier aggregation scenario 31, a second carrier aggregation scenario 32, and a third carrier aggregation scenario 33, which schematically depict three types of carrier aggregation.

The carrier aggregation scenarios 31-33 illustrate different spectrum allocations for a first component carrier f_{UL1}, a second component carrier f_{UL2}, and a third component carrier f_{UL3}. Although FIG. 2B is illustrated in the context of aggregating three component carriers, carrier aggregation can be used to aggregate more or fewer carriers. Moreover, although illustrated in the context of uplink, the aggregation scenarios are also applicable to downlink.

The first carrier aggregation scenario 31 illustrates intra-band contiguous carrier aggregation, in which component carriers that are adjacent in frequency and in a common frequency band are aggregated. For example, the first carrier aggregation scenario 31 depicts aggregation of component carriers f_{UL1}, f_{UL2}, and f_{UL3} that are contiguous and located within a first frequency band BAND1.

With continuing reference to FIG. 2B, the second carrier aggregation scenario 32 illustrates intra-band non-continuous carrier aggregation, in which two or more components carriers that are non-adjacent in frequency and within a common frequency band are aggregated. For example, the second carrier aggregation scenario 32 depicts aggregation of component carriers f_{UL1}, f_{UL2}, and f_{UL3} that are non-contiguous, but located within a first frequency band BAND1.

The third carrier aggregation scenario 33 illustrates inter-band non-contiguous carrier aggregation, in which component carriers that are non-adjacent in frequency and in multiple frequency bands are aggregated. For example, the third carrier aggregation scenario 33 depicts aggregation of component carriers f_{UL1} and f_{UL2} of a first frequency band BAND1 with component carrier f_{UL3} of a second frequency band BAND2.

FIG. 2C illustrates various examples of downlink carrier aggregation for the communication link of FIG. 2A. The examples depict various carrier aggregation scenarios 34-38 for different spectrum allocations of a first component carrier f_{DL1}, a second component carrier f_{DL2}, a third component carrier f_{DL3}, a fourth component carrier f_{DL4}, and a fifth component carrier f_{DL5}. Although FIG. 2C is illustrated in the context of aggregating five component carriers, carrier aggregation can be used to aggregate more or fewer carriers. Moreover, although illustrated in the context of downlink, the aggregation scenarios are also applicable to uplink.

The first carrier aggregation scenario 34 depicts aggregation of component carriers that are contiguous and located within the same frequency band. Additionally, the second carrier aggregation scenario 35 and the third carrier aggregation scenario 36 illustrates two examples of aggregation that are non-contiguous, but located within the same frequency band. Furthermore, the fourth carrier aggregation scenario 37 and the fifth carrier aggregation scenario 38 illustrates two examples of aggregation in which component carriers that are non-adjacent in frequency and in multiple frequency bands are aggregated. As the number of aggregated component carriers increases, a complexity of possible carrier aggregation scenarios also increases.

With reference to FIGS. 2A-2C, the individual component carriers used in carrier aggregation can be of a variety of frequencies, including, for example, frequency carriers in the same band or in multiple bands. Additionally, carrier aggregation is applicable to implementations in which the individual component carriers are of about the same bandwidth as well as to implementations in which the individual component carriers have different bandwidths.

Certain communication networks allocate a particular user device with a primary component carrier (PCC) or anchor carrier for uplink and a PCC for downlink. Additionally, when the mobile device communicates using a single frequency carrier for uplink or downlink, the user device communicates using the PCC. To enhance bandwidth for uplink communications, the uplink PCC can be aggregated with one or more uplink secondary component carriers (SCCs). Additionally, to enhance bandwidth for downlink communications, the downlink PCC can be aggregated with one or more downlink SCCs.

In certain implementations, a communication network provides a network cell for each component carrier. Additionally, a primary cell can operate using a PCC, while a secondary cell can operate using a SCC. The primary and secondary cells may have different coverage areas, for instance, due to differences in frequencies of carriers and/or network environment.

License assisted access (LAA) refers to downlink carrier aggregation in which a licensed frequency carrier associated with a mobile operator is aggregated with a frequency carrier in unlicensed spectrum, such as Wi-Fi. LAA employs a downlink PCC in the licensed spectrum that carries control and signaling information associated with the communication link, while unlicensed spectrum is aggregated for wider downlink bandwidth when available. LAA can operate with dynamic adjustment of secondary carriers to avoid Wi-Fi users and/or to coexist with Wi-Fi users. Enhanced license assisted access (eLAA) refers to an evolution of LAA that aggregates licensed and unlicensed spectrum for both downlink and uplink.

As described above wireless devices typically receive multiple wireless signals of different frequency bands. In some implementations, the different frequency bands are associated with different technologies, communication standards, or features of the wireless device. For example, in addition to the wireless device being capable of communication using Wi-Fi technology and cellular technology (e.g., 4G, 4G LTE, 5G, and the like), a wireless device may also include geolocation services, such as those provided by or enabled by the Global Positioning System (GPS).

A front-end module (FEM) may process any or at least some of the signals received by a wireless device before providing the processed signals to a receiver or transceiver within the wireless device. Processing the received signals may include filtering out undesired signals. These undesired signals may be associated with frequency bands not supported by the particular receiver. In some implementations, some of the undesired signals may be associated with frequency bands supported by other receivers within the wireless device. Thus, the undesired signals may be noise for a particular receiver, but may be the target or desired signals for another receiver within the wireless device.

Regardless of whether the undesired signals are general noise or interference, or are communication signals to be received by another FEM or receiver within the wireless device, the undesired signals may be problematic for a particular receiver because the undesired signals may mask the desired signal or desensitize the FEM or receiver due to intermodulation and/or harmonic interference. For example, a GPS FEM may be configured to process L1 GPS signals (e.g., GPS signals of approximately 1.575 GHz). However, the GPS FEM may also receive 2.4 GHz Wi-Fi signals and 800 MHz Long-Term Evolution (LTE) signals (or band 13 LTE signals). The intermodulation of the 2.4 GHz Wi-Fi signals with the 800 MHz LTE signals is approximately 1.6 GHz. The intermodulation frequency in this example is close enough to the frequency of the GPS signal to mask the GPS signal or to cause noise within the GPS signal. Further, the second harmonic of the 800 MHz LTE signal is also approximately 1.6 GHz, which may further cause interference with identifying the GPS signal. For example, the LTE Band 13 is 777-787 MHz and has a second harmonic of 1554-1574 MHz, and the LTE Band 14 is 788-798 MHz and has a second harmonic of 1576-1596 MHz. In other words, both Band 13 and 14 have second harmonics that are approximately equal to or very close to the GPS frequency. Thus, in some implementations, harmonic interference may mask a received GPS signal or otherwise introduce noise that causes interference in the signal.

Further, in some instances, interference may also be caused by intermodulation (IMD) interference as described above. In some instances, the majority of the interference may be caused by second order intermodulation (IM2) products. For example, an LTE Band 8 signal of 915 MHz and a 2.4 GHz Wi-Fi signal of 2472 MHz may result in a second order intermodulation product of 1557 MHz, which is close to the GPS frequency band of 1.575 GHz. As another example, an LTE Band 26 signal of 840 MHz and a 2.4 GHz Wi-Fi signal of 2415 MHz may result in a second order intermodulation product of 1575 MHz, which is equal to the GPS frequency band of 1.575 GHz. Thus, IM2 products may interfere or otherwise introduce noise that reduces the capability of a receiver to distinguish GPS signals.

As mentioned above, some wireless devices may be configured to support multiple receivers or multiple frequency bands. Further, in some implementations, a wireless device may support carrier aggregation, or the aggregation of multiple frequency bands as part of a single transmission signal or receive signal. Regardless of whether a received signal is part of a carrier aggregated signal or whether multiple frequency bands are received due to an antenna supporting multiple frequency bands, it is often desirable to split the signals into constituted frequencies or frequency bands. For example, often, different frequency bands are supported by different receivers and thus, are split so as to be provided to the supported receiver.

To split the signals, a filter may be used that can propagate or transmit a signal to a particular receive path and/or to a particular receiver. This filter may filter out undesired signals such as undesired harmonics or intermodulation products. Further, the filter may divide a signal into constituted frequency bands and propagate the different frequency bands to particular receivers or receive paths. The filter may be an acoustic filter and can sometimes be referred to as an “antennaplexer” or an “antenna-plexer.”

As wireless devices support more frequency bands due, for example, to new technologies and/or the support of more features, the previously described problems of harmonic interference and intermodulation distortion increases. The increased noise and distortion impacts the quality of wireless communication and the speed of communication. Existing antennaplexers have insufficient noise suppression and interference reduction for many implementations, including 5G communication.

The present disclosure introduces improved FEMs and antennaplexers that are capable of splitting Tx signals and/or Rx signals into different frequency bands. The improved antennaplexers may provide improved harmonic and intermodulation distortion (IMD) rejection. The antennaplexers of the present disclosure may use stacked or split resonators with MIM CAPs according to the present disclosure to improve performance of Tx and/or Rx signal propagation.

The antennaplexer can substitute one or more of the resonators in a stacked resonator circuit with a capacitor. The introduction of the capacitor can reduce the non-linearity of the received signals. In some implementations, the capacitor may be a MIM CAP according to this disclosure. The combination of the stacked resonators and the capacitor substitution for a resonator may improve linearity of the antennaplexer and provide for sharper rejection of undesired signals. Thus, the wireless device can support a greater number of frequency bands and/or frequency bands that are more likely to cause harmonic interference and/or IMD distortion.

The resonators used in aspects and embodiments disclosed herein may be acoustic wave resonators. An acoustic wave resonator including any suitable combination of features disclosed herein can be included in a filter arranged to filter a radio frequency signal in a 5G NR operating band within FR1. A filter arranged to filter a radio frequency signal in a 5G NR operating band can include one or more acoustic wave resonators as disclosed herein. FR1 can be from 410 MHz to 7.125 GHz, for example, as specified in a current 5G NR specification. One or more acoustic wave resonators in accordance with any suitable principles and advantages disclosed herein can be included in a filter arranged to filter a radio frequency signal in a 4G LTE operating band and/or in a filter with a passband that spans a 4G LTE operating band and a 5G NR operating band. As an additional example, one or more acoustic wave resonators in accordance with any suitable principles and advantages disclosed herein can be included in a filter arranged to filter a radio frequency signal in a global positioning system (GPS) receiver.

Much of the present disclosure relates to MIM CAPs facilitating interference reduction that may affect the ability of a receiver to receive or distinguish signals from other signals. For example, an antennaplexer described herein may receive or distinguish GPS signals from other signals to provide to a GPS receiver. It should be understood that the present disclosure may be applied to other receivers and is not limited to GPS receivers. For example, aspects of the present disclosure may be applied to Wi-Fi receivers, 4G receivers, 5G receivers, and the like. Further, many of the examples described herein relate to a GPS L1 triplexer. But the present disclosure is not limited as such, and aspects disclosed herein can be applied to any frequency band filter using acoustic wave resonators.

### Example Wireless Device

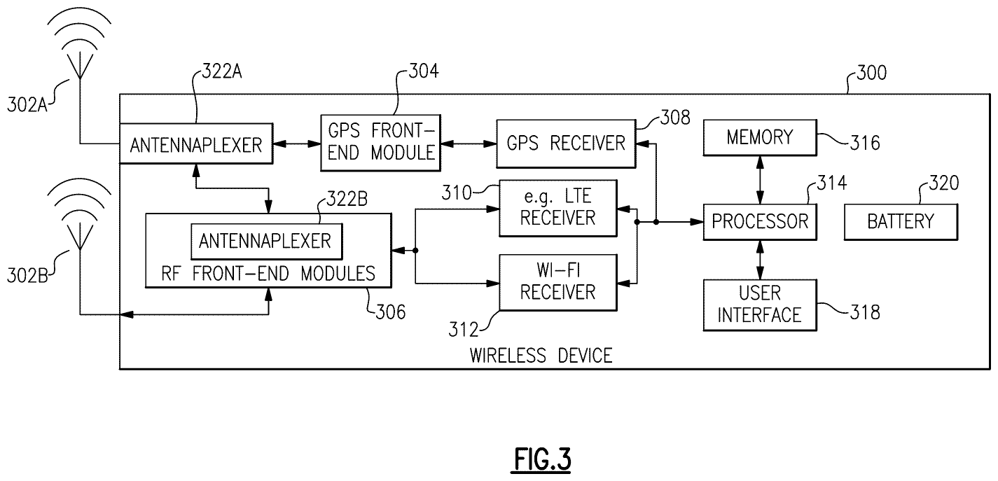

FIG. 3 illustrates a block diagram of an aspect of a wireless device 300. The wireless device 300 may include any type of wireless device that is configured to receive wireless signals. In some implementations, the wireless device 300 may include any type of wireless devices capable of processing a plurality of wireless signals using a plurality of technologies, communication standards, or features of the wireless device 300. For example, the wireless device 300 may be a cellular phone (including a smart phone or a dumb phone), a tablet device, a laptop, a smartwatch, a pair of smart glasses, or any other wearable device, internet-of-things (IOT) device, or computing device that may include wireless capability.

The example illustrated in FIG. 3 is of a wireless device that includes the capability of receiving a GPS signal, a Wi-Fi signal, and a 4G LTE signal. However, the wireless device 300 is not limited as such and may include wireless devices that are capable of receiving and/or processing fewer or greater numbers of wireless signals, or other types of wireless signals. For example, the wireless device 300 may be capable of receiving Bluetooth® signals, 5G signals, near-field communication (NFC) signals, and the like.

The wireless device 300 may include one or more antennas 302A, 302B (which may be referred to in the singular as antenna 302 or collectively as antennas 302). The antennas 302 may be configured to receive one or more signals of one or more different frequencies or frequency bands. For example, the antennas 302 may receive signals having frequencies associated with GPS (e.g., 1.575 GHz), Wi-Fi (e.g., 2.4 GHz), or cellular communication (e.g., 800 MHz). It should be understood that any particular antenna 302 may be configured to receive signals of a plurality of different frequency bands. For example, the antenna 302A may be configured to receive any of the signals in the aforementioned example (e.g., signals from between 800 MHz to 2.4 GHz).

Signals received at the antennas 302 may be provided to one or more FEMs within the wireless device 300. The wireless device 300 may include a GPS FEM 304 and one or more additional RF FEMs 306. It should be understood that the GPS FEM 304 may also be an RF FEM in that GPS signals are within the radio frequency band.

In some aspects of the wireless device 300, the signals received at the antennas 302 may be provided to an antennaplexer 322A, 322B (which may be referred to in the singular as antennaplexer 322 or collectively as antennaplexers 322). The antennaplexers 322 may direct a received signal to a particular FEM 304, 306 and/or to a particular receiver 308, 310, 312. The antennaplexers 322 may include one or more filters that cause the antennaplexers 322 to direct the received signals from the antenna to the particular FEM 304, 306 and/or to a particular receiver 308, 310, 312. In some implementations, the filters of the antennaplexers 322 include band-pass filtering that permits a desired frequency band to be communicated to the FEM and/or receiver. Further, the filters of the antennaplexers 322 may prevent or reduce harmonic frequencies, noise, or IMD interference.

As illustrated in FIG. 3 by the antennaplexer 322A, in some implementations, the antennaplexer may be a separate circuit element that is positioned between the antenna 302 and the FEMs 304, 306. In such implementations, the antennaplexer 322A can direct a received signal to a particular FEM 304, 306 based on the frequency band of the received signal. In other implementations, as illustrated by the antennaplexer 322B, the antennaplexer may be included in a FEM, and can direct a signal to a particular receiver 310, 312 based on the frequency band of the received signal. In certain aspects, the configuration of the resonators and/or filters within the antennaplexers 322 may be responsible for the directing of signals of particular frequency bands along particular transmission paths or to particular FEMs or receivers.

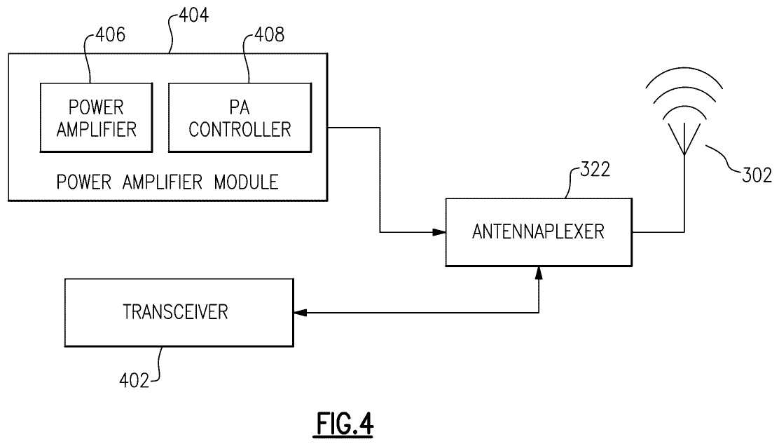

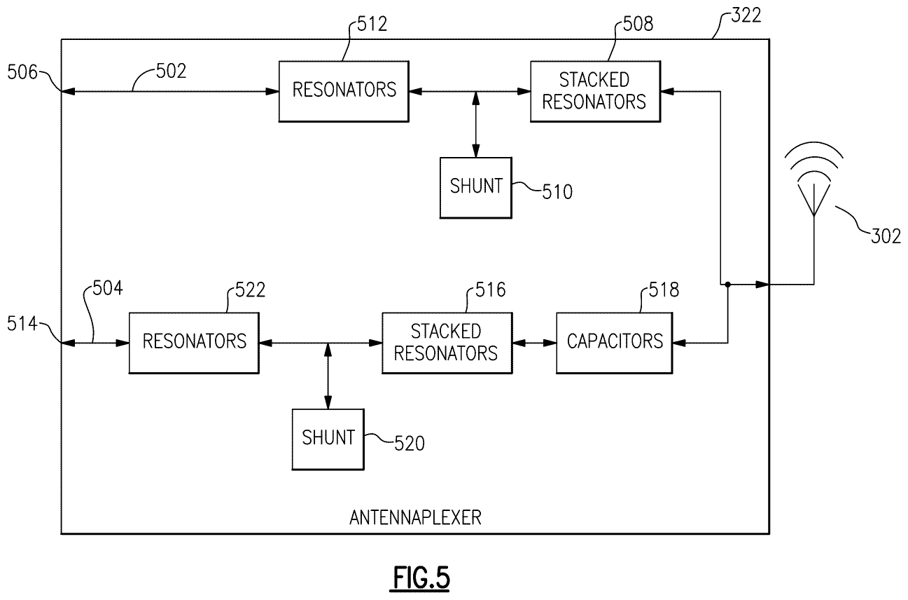

FIG. 4 illustrates a block diagram of some additional configurations of the wireless device 300 with an antennaplexer 322. As illustrated, the antennaplexer 322 (which may be an acoustic wave filter) may be connected to an antenna 302 from which the antennaplexer 322 may receive signals of one or more different frequencies. Further, the antennaplexer 322 may transmit signals of one or more frequencies via the antenna 302. The antennaplexer 322 may be in communication with one or more transceivers 402, such as one or more cellular transceivers (e.g., 3G, 4G, 4G LTE, or 5G transceivers), a GPS receiver, or a Wi-Fi transceiver. Alternatively, or in addition, the antennaplexer 322 may be in communication with one or more power amplifier modules 404. The power amplifier modules 404 may be included as part of a transceiver 402 or in a FEM (not shown). The power amplifier module 404 may include one or more power amplifiers 406. Further, the power amplifier module 404 may include a power amplifier controller 408 that may set or adjust the configuration of the power amplifier 406 and/or the voltage supplied to the power amplifier 406.

Returning to FIG. 3, although multiple antennaplexers 322 are illustrated, it should be understood that the wireless device may include a single antennaplexer 322. The antennaplexer 322 may be configured to communicate with a single antenna and may direct signals of different frequency bands to different transceivers. Alternatively, the antennaplexer 322 may be configured to communicate with multiple antennas and may direct signals to different receivers from different antennas and/or to different antennas from different transmitters.

The GPS FEM 304 may include any FEM that is capable of processing signals within one or more GPS frequency bands. Further, the GPS FEM 304 may include any type of FEM that is capable of performing pre-filtering before providing a received signal to a receiver, such as the GPS receiver 308. As will be described in more detail below, the GPS FEM 304 may include additional out-of-band filtering capability that reduces or prevents the occurrence of harmonic interference and/or intermodulation interference.

The RF FEMs 306 may include one or more FEMs that are capable of processing signals within one or more RF frequency bands. For example, the RF FEMs 306 may include FEMs capable of processing Wi-Fi signals or LTE cellular communication signals. In some embodiments, the RF FEMs 306 may include similar capabilities as the GPS FEM 304 enabling the reduction or prevention of the occurrence of harmonic interference and/or intermodulation interference within target frequency bands for the particular RF FEMs 306. For example, for an RF FEM 306 configured to process signals for LTE cellular communications, the RF FEM 306 may be configured to reduce or prevent harmonic interference and/or intermodulation interference within one or more of the LTE cellular communication frequency bands.

The GPS FEM 304 may isolate, identify, or pass signals associated with a GPS frequency while reducing or blocking out-of-band signals not associated with GPS. The filtered GPS signals may be amplified using, for example, a low noise amplifier (LNA) in the GPS FEM and then the amplified GPS signals may be provided to the GPS receiver 308. The GPS receiver 308 may include any type of receiver that can process the amplified GPS signals. The GPS receiver 308 may further filter the amplified GPS signals. In addition, the GPS receiver 308 may include frequency down-conversion, such as via a demodulator, and may demodulate the signal received from the GPS FEM 304. Further, the GPS receiver 308 may include analog-to-digital conversion that can convert the analog signal received from the GPS FEM 304 to a digital signal, which may then be processed by the processor 314.

In some embodiments, the wireless device 300 may further include additional filters and/or amplifiers between the GPS FEM 304 and the GPS receiver 308. Further, in some embodiments, the GPS receiver 308 may be part of a transceiver.

The wireless device 300 may further include one or more additional receivers configured to receive filtered and/or amplified signals from the one or more additional RF FEMs 306. For example, the wireless device 300 includes an LTE receiver 310 capable of processing LTE signals and a Wi-Fi receiver 312 capable of processing Wi-Fi signals.

The receivers 308, 310, and 312 may each be in communication with the processor 314. The processor 314 may provide any suitable baseband processing functions for the wireless device 300. Further, the processor 314 may provide any general processing capability for the wireless device 300.

The FEMs 304, 306 and/or the receivers 308, 310, 312 may include differential-based circuitry. For example, the FEMs 304, 306 and/or the receivers 308, 310, 312 may include differential low noise amplifiers (LNAs). One or more acoustic wave filters (e.g., SAW or BAW filters) may convert a received signal to a differential signal to provide to the LNAs.

The memory 316 can store any suitable data for the wireless device 300. Further, the memory 316 may include any type of memory including both volatile and non-volatile memory.

The user interface 318 may include any type of user interface capable of receiving user inputs and/or outputting data to a user. For example, the user interface 318 may include a display, a touchscreen, one or more interactive user interface devices (e.g., buttons, sliders, capacitive sensors, resistive sensors, and the like), or any other user interface elements.

The wireless device 300 may further include a battery 320 or other power source capable of powering the wireless device 300 and/or one or more elements of the wireless device 300. The battery 320 may include rechargeable batteries. Further, the battery 320 may include or be replaced by any other type of power supply system.

### Example Antennaplexer

FIG. 5 illustrates a block diagram of an antennaplexer 322 in accordance with certain aspects of the present disclosure. It should be understood that the block diagram of FIG. 5 is one non-limiting example of the antennaplexer 322 and that other configurations of the antennaplexer 322 are possible. For example, the antennaplexer 322 may have different configurations based on the particular frequency bands and/or transceivers supported by the wireless device 300. For instance, if the wireless device supports three receivers and/or three frequency bands, the antennaplexer 322 may have a third transmission path within the antennaplexer 322 configured to support a third frequency band. Moreover, as will be explained further below, different transmission paths or transmission line configurations may be used to support different frequency bands.

The antennaplexer 322 of FIG. 5 includes two transmission paths 502, 504. The first transmission path 502 is capable of receiving signals of a first frequency band from the antenna 302 and outputting them via a port 506 to a receiver. In some aspects, the antennaplexer 322 may receive signals of the first frequency band from the port 506 for transmission via the antenna 302. The first transmission path 502 may filter out signals not of the first frequency band. The filtering may not only reduce or eliminate signals of unsupported frequency bands, but may also reduce harmonic interference and/or IMD distortion or interference.

The first transmission path 502 may include a set of stacked resonators 508, a shunt 510, and optionally, one or more additional resonators 512. The use of resonators for filter components in place of an LC circuit may result in improved performance. However, the resonators may also introduce nonlinearities into the filters.

The number of resonators and the configuration of the resonators may be based on the desired frequency band. Further, the use of the stacked resonators enables a sharper rejection of undesired signals compared to traditional filters improving the rejection of the harmonic frequencies and/or the frequencies that cause IMD interference. By splitting the signal across the stacked resonators, the voltage may be reduced across each resonator generating less harmonic noise. Moreover, the voltage divider formed by the stacked resonators may reduce the non-linearity of the signal processed by the transmission path 502.

The second transmission path 504 is capable of receiving signals of a second frequency band from the antenna 302 and outputting them via a port 514 to a receiver. The receiver in communication with the port 514 may differ from the receiver in communication with the port 506. In some aspects, the antennaplexer 322 may receive signals of the second frequency band from the port 514 for transmission via the antenna 302. The second transmission path 504 may filter out signals not of the second frequency band, such as signals of the first frequency band that are processed via the first transmission path 502. Similarly, the first transmission path may filter out signals of the second frequency band. As stated above, the filtering may reduce or eliminate signals of unsupported frequency bands, and may also reduce harmonic interference and/or IMD distortion or interference.

The second transmission path 504 may include a set of stacked resonators 516 in series with one or more capacitors 518. In some implementations, the one or more capacitors may replace a resonator of the stacked resonators 516. By replacing a resonator in the stacked resonators 516 with a capacitor 518, the linearity of the applied signal may be improved. In other words, in some aspects, the non-linearity of the applied signal may be reduced. Generally, acoustic wave resonators have worse linearity than a capacitor. In certain aspects, by using a capacitor 518 to replace one of the stacked resonators, the total non-linearity created from stacked resonators may be reduced. For example, each resonator of a pair of stacked resonators may introduce some non-linearity. Replacing one of the resonators with a capacitor may eliminate the contribution of non-linearity by the resonator being replaced. In other words, only the remaining resonator from the pair of resonators will contribute to the total non-linearity. Moreover, in some implementations, the stacked resonators 516 may be replaced with a single resonator stacked with a capacitor.

In some implementations, because the capacitor 518 is stacked with the resonators 516, the size of each resonator included in the stacked resonators 516 may be increased compared to the size of the resonators without the stacked capacitor (e.g., compared to the stacked resonators 508). For example, in some implementations, each resonator included in the stacked resonators 516 may be approximately 1.5 times the size of the resonators included in the stacked resonators 508. This increase in size may be when the stacked resonators 516 are stacked with a single capacitor. The stacking of additional capacitors with the stacked resonators 516 may further increase the size of each resonator. Increasing the size of the resonator may include increasing the area of the resonator. In implementations with two stacked capacitors, the area of each resonator may be doubled. As another example, in implementations that use three stacked capacitors stacked with the resonators 516, each resonator may be tripled in area. Thus, in some implementations, the improved linearity that may be obtained by replacing a resonator with a capacitor may have a trade-off of increased size for the antennaplexer.

Further, the second transmission path may include a shunt 520, and optionally, one or more additional resonators 522. The number of resonators and the configuration of the resonators, and the number and size of the capacitors 518 may be based on the desired frequency band. Further, the use of the stacked resonators in series with the capacitors enables a sharper rejection of undesired signals compared to traditional filters, improving the rejection of the harmonic frequencies and/or the frequencies that cause IMD interference. Moreover, the substitution of a resonator with a capacitor provides a further reduction in non-linearity compared to traditional filters or the use of resonators alone.

It should be understood that one or more additional circuit elements may be included as part of the transmission paths 502, 504. For example, one or more resistors, inductors, or capacitors may be included to facilitate impedance matching or filtering of noise within the transmission paths. Further, as will be discussed in more detail below, the antennaplexer 322 may include one or more transmission paths or filters that are implemented using inductor-capacitor circuits instead of resonators.

### Example Antennaplexer Circuit

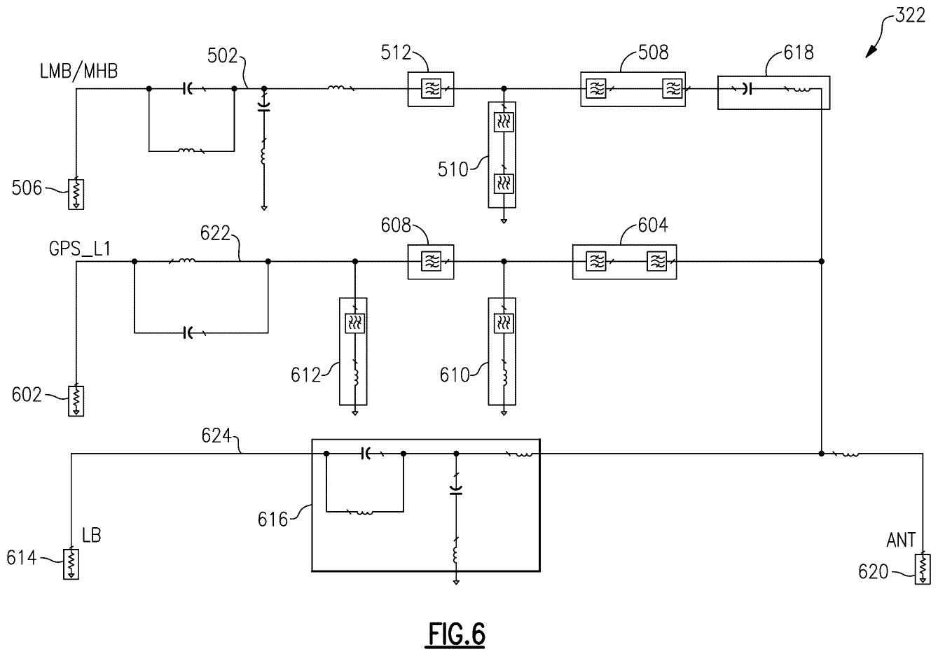

FIG. 6 illustrates a circuit diagram of an antennaplexer 322 in accordance with certain aspects of the present disclosure. As previously described, the antennaplexer 322 may be positioned between an antenna and one or more receivers or FEMs. Thus, the antennaplexer 322 may have an antenna port 620 connected to an antenna, and a plurality of ports connected to one or more receivers, transmitters, or FEMs. For example, the antennaplexer 322 of FIG. 6 may have a port 506 that connects to a receiver configured to process low mid-band or mid high-band (LMB/MHB) receive signals (e.g., frequencies between 1.5 to 2.2 GHz). As another example, the antennaplexer 322 may have a port 602 configured to connect to a GPS receiver configured to process the GPS L1 band centered around 1.575 GHz. In yet another example, the antennaplexer 322 may have a port 614 configured to connect to a low-band receiver configured to process low-band signals (e.g., frequencies below 0.95 GHz).

Each port may connect to a different transmission path 502, 622, 624 between the port and the antenna port 620. Each transmission path 502, 622, 624 may be configured as a filter configured to permit communication of signals of a particular frequency while blocking signals of other frequencies. For example, the transmission path 502 between the antenna port 620 and the LMB/MHB port 506 may permit signals associated with LMB/MHB frequencies (e.g., frequencies between 1.5 to 2.2 GHz) while blocking other frequencies. It should be understood that the filter of the transmission path 502 may be configured to permit more or less of the frequency band 1.5 to 2.2 GHz. The transmission path 622 may be configured to permit GPS frequencies (e.g., a frequency band centered around 1.575 GHz) while blocking other frequency bands. And the transmission path 624 may be configured to permit low-band frequencies (e.g., frequencies below 0.95 GHz) while blocking other frequencies. It should be understood that each of the transmission paths 502, 622, 624 may be configured to support different frequency bands than those of the above examples. Further, the antennaplexer 322 may include more or fewer transmission paths.

The transmission path 502 may include a filter implemented using a stacked resonator 508 on a main transmission path. Further, the filter may include a second stacked resonator in a shunt circuit 510 of the transmission path 502. As illustrated by the shunt circuits 610 and 612 of the transmission path 622, the shunt circuits may be implemented using a single resonator instead of a stacked resonator. The determination of whether to use stacked resonators or a single resonator may depend on the particular frequency band to be communicated and the desired rejection of harmonics and IMD distortion as well as the desired linearity of the signal to be communicated. Further, the configuration of the resonators may depend on the space available for the antennaplexer 322 within the wireless device 300.

Returning to the transmission path 502, the filter path may have one or more additional resonators 512 between the shunt circuit 510 and the port 506. In some implementations, the transmission path 502 may include an inductor-capacitor network or an inductor-capacitor circuit 618 between the antenna port 620 and the stacked resonator 508. This additional inductor-capacitor circuit 618 may create notches out of the passband, and help match the impedance to a target impedance, usually, but not necessarily 50 Ohms. Further, the transmission path 502 may have one or more additional inductor-capacitor circuits between the resonators and the port 506. These additional inductor-capacitor circuits may be used to facilitate impedance matching and/or to provide additional noise filtering within the receive signal. Each of the additional LC circuits illustrated in the transmission paths 502, 622, and 624 may be used to provide frequency rejection notches at designated frequencies within the corresponding transmission paths 502, 622, and 624. Although the stacked resonator 508 and the stacked resonator of the shunt circuit 510 are illustrated as a pair of resonators, it should be understood that the stacked resonators may include more than two resonators. By increasing the number of resonators stacked together, the harmonic rejection and the IMD rejection may be improved. Further, linearity may be improved. However, increasing the number of resonators may result in an increase in the size of each resonator. Thus, in some implementations, it may be desirable to not add more than two or three resonators to prevent the antennaplexer 322 from using valuable space within the wireless device 300.

The transmission path 622 represents an alternative configuration to the transmission path 502 that is configured to support (e.g., communicate) different frequency bands than the transmission path 502. In other words, the antennaplexer 322 may function as a multiplexer permitting different frequencies to traverse different communication paths based on the configuration of the transmission paths. The transmission path 622 includes a stacked resonator 604, which may include two or more resonators. As with the stacked resonator 508, more resonators may be stacked to improve the accuracy of the filter. However, the inclusion of additional resonators may, in some implementations, expand the size of the filter. For example, in some implementations, to maintain the transmission speed of the transmission path, it may be desired to increase the area of each resonator for each additional resonator added to the stacked resonator circuit. Thus, in some implementations, each resonator may increase in size for each additional resonator added to the stacked resonator circuit. For example, if a third resonator is added, the size of each resonator may be increased by about 1.5 times in size or area so as to maintain the transmission speed of a signal through the transmission path.

The transmission path 622 may further include a pair of shunt circuits 610, 612 surrounding an additional resonator 608. Each of the shunt circuits 610, 612 may include a stacked resonator and/or a resonator-inductor circuit as illustrated in FIG. 6.

The transmission path 624 illustrates a non-resonator based filter path. The filter of the transmission path 624 may be an inductor-capacitor circuit (an LC circuit). In some implementations, one or more of the supported frequency bands may be sufficiently distinct or separate from other supported frequency bands that the improved noise, harmonic, and IMD rejection is unnecessary. In such implementations, a resonator-based filter path may be omitted and an LC circuit may be used for the filter as illustrated with the transmission path 624. As previously described, the LMB/MHB path may include frequencies between 1.5 to 2.2 GHz and the GPS path may include frequencies around 1.575 GHz. Accordingly, as the two paths may include frequencies that are relatively near to each other, an improved filter may be desired. However, as the LB filter path may be associated with frequencies that are not close to the other supported frequencies (e.g., less than 0.95 GHz), in some implementations it is unnecessary to have the improved noise, harmonic, and IMD rejection, and the use of an LC filter may be sufficient. In other implementations, even when the supported frequency bands are not close in frequency, it may still be desirable to use a stacked resonator based filter because IM2 interference or harmonic noise may cause interference with a desired signal.

### Second Example Antennaplexer

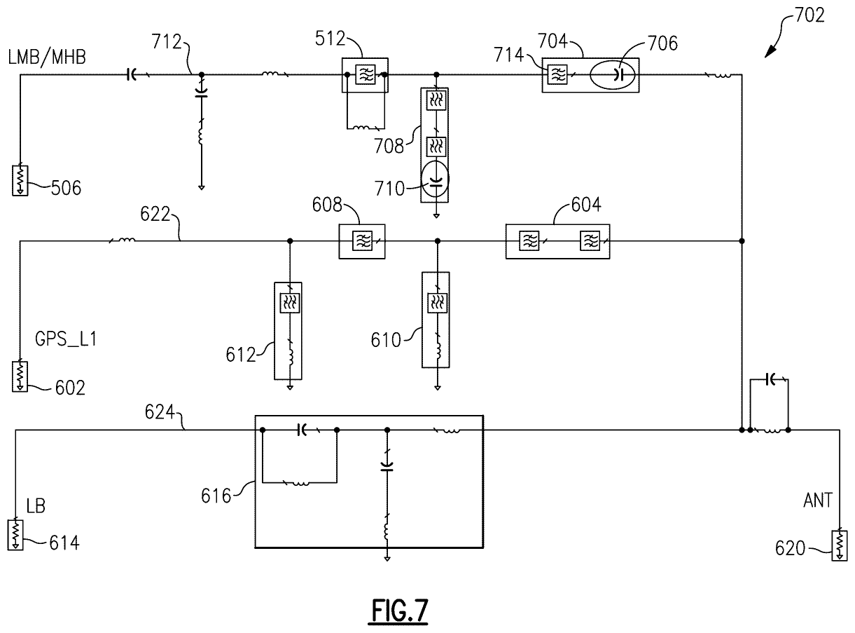

FIG. 7 illustrates a circuit diagram of an alternative antennaplexer 702 in accordance with certain aspects of the present disclosure. The antennaplexer 702 may include one or more of the features described with respect to the antennaplexer 322. For example, the antennaplexer 702 may include the transmission paths 622 and 624. Further, the antennaplexer 702 may include a transmission path 712 configured to permit communication or transmission of signals of an LMB/MHB frequency through the transmission path 712 while blocking other frequencies.

The transmission path 712 may include a resonator circuit 704. The resonator circuit 704 may include a resonator 714 stacked, or connected serially, with a capacitor 706 in place of a second resonator. Advantageously, in certain implementations, replacing a resonator with a capacitor in the resonator circuit 704 may result in improved harmonic and IMD rejection compared to an antennaplexer that uses stacked resonators and/or compared to antennaplexers that use LC filters instead of resonators. In some implementations, the resonator circuit 704 may include stacked resonators in series with a capacitor 706. The capacitor 706 may substitute for an additional resonator that may be or may have been stacked with the stacked resonators but for the substitution of the capacitor 706. In other words, in one example, a stacked resonator that may originally have been designed or may have three resonators may instead be designed with two resonators and a capacitor 706.

Further, in some implementations, a capacitor 710 may be added to the stacked resonators of the shunt circuit 708. In some implementations, the capacitor 710 may replace or substitute for a resonator in the shunt circuit 708. Thus, the shunt circuit 708 may have a similar configuration to the series resonator circuit 704. Moreover, in some implementations, additional resonators 714 and/or capacitors 706 may be stacked to the resonator circuit 704. Similarly, additional resonators or capacitors 710 may be stacked to the shunt circuit 708. In certain implementations, a designer of the antennaplexer, or an automated design computing system, may design the filter circuits using resonators to obtain the desired filtering (e.g., to permit and/or block the desired frequency bands). The designer may then split the resonators into stacks of two, three, or more resonators. One or more of the resonators may then be replaced with one or more capacitors of an equivalent size based on the equivalent capacitance. In certain implementations, substituting a capacitor 710 for a resonator in the shunt circuit 708, or adding a capacitor 710 to one or more resonators of the shunt circuit 708 may improve the harmonic and/or IMD rejection compared to an antennaplexer using LC filters or resonators without a series capacitor.

The capacitors 706, 710 may be metal-insulator-metal (MIM) capacitors. Alternatively, or in addition, other types of capacitors may be utilized for the capacitors 706, 710. For example, the capacitors 706, 710 can include any type of surface mounted capacitor, such as ceramic or electrolytic capacitors.

### Example Resonator

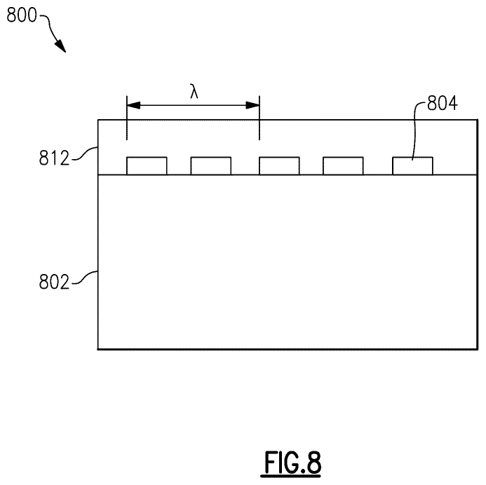

FIG. 8 is a cross-sectional diagram of a temperature compensated SAW (TCSAW) resonator 800 according to certain aspects of the present disclosure. The TCSAW resonator 800 is one non-limiting example of a resonator that may be included in the stacked resonator circuits described herein (e.g., resonator circuits 508 or 704, etc.), or any of the other resonator circuits described herein, including in the various shunt circuits described herein (e.g., the shunt circuits 510, 610, or 708, etc.). In certain aspects, the resonators used in the circuits described herein may be other than TCSAW resonators. For example, the resonators may be non-temperature compensated SAW resonators. In other implementations, the resonators may be surface acoustic wave (SAW) resonators, bulk acoustic wave (BAW) resonators, or thin-film bulk acoustic wave resonators.

The TCSAW resonator 800 is an example of an acoustic wave resonator that can have a relatively narrow IDT electrode aperture. The illustrated TCSAW resonator 800 includes a piezoelectric material layer 802, an IDT electrode 804 on the piezoelectric material layer 802, and a temperature compensation layer 812 over the IDT electrode 804. The piezoelectric material layer 802 can be a lithium niobate (LN) substrate or a lithium tantalite (LT) substrate, for example. The IDT electrode 804 can have a relatively narrow aperture to concentrate a transverse spurious mode in frequency. The IDT electrode 804 can be implemented in accordance with any suitable principles and advantages of the IDT electrode with a narrow aperture disclosed herein. The TCSAW resonator 800 can be included as a series resonator in a filter to improve filter skirt steepness. The TCSAW resonator 800 can be included as a shunt resonator in a filter to improve filter skirt steepness.

The temperature compensation layer 812 can bring the temperature coefficient of frequency (TCF) of the TCSAW resonator 800 closer to zero relative to a similar SAW resonator without the temperature compensation layer 812. The temperature compensation layer 812 can have a positive TCF. This can compensate for the piezoelectric material layer 802 having a negative TCF. The temperature compensation layer 812 can be a silicon dioxide (SiO₂) layer. The temperature compensation layer 812 can include any other suitable temperature compensating material including without limitation a tellurium dioxide (TeO₂) layer or a silicon oxyfluoride (SiOF layer). The temperature compensation layer 812 can include any suitable combination of SiO₂, TeO₂, and/or SiOF.

### Example MIM CAPs

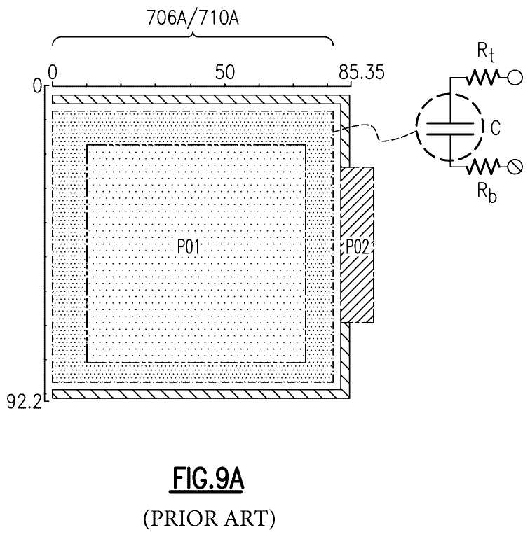

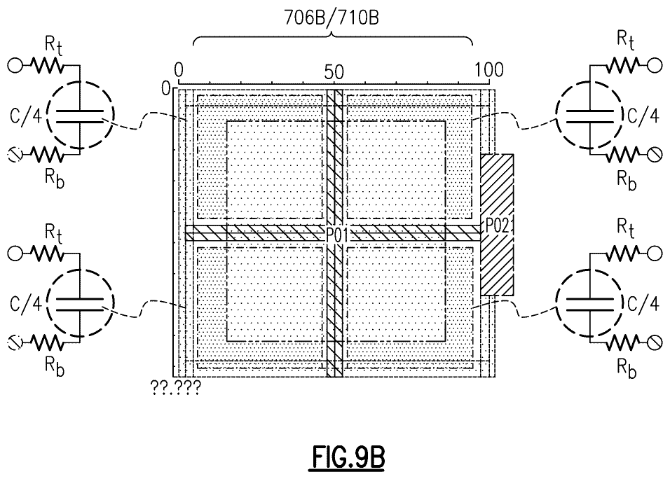

FIG. 9A illustrates a top view on a conventional MIM CAP and a corresponding equivalent circuit diagram for the MIM CAP having a capacitance C. The MIM CAP may, for example, correspond to one or more of the capacitors 706 or 710 shown in FIG. 7.

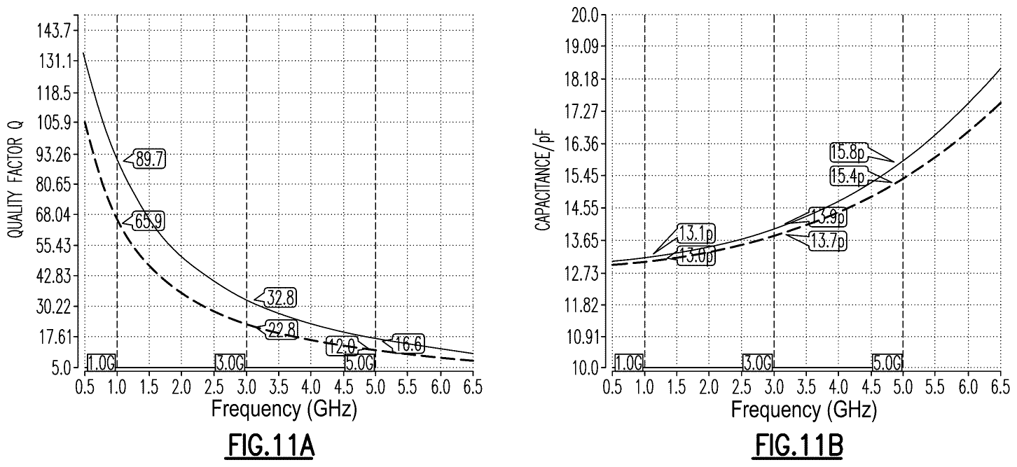

The MIM CAP may have a capacitance of approximately 12 pF. The capacitance may be in the range between 12.7 pF and approximately 17.5 pF at frequencies in the range between 0.5 and 6.5 GHz, as illustrated in FIG. 11B.

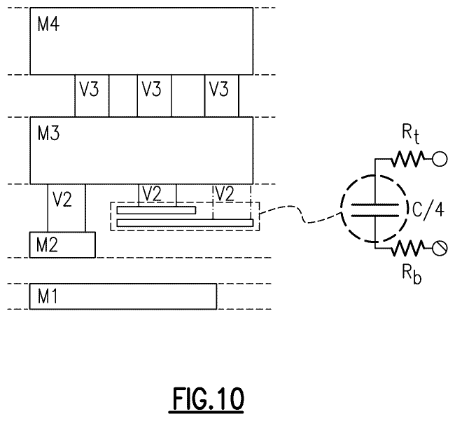

The MIM CAP may have a single 80 μm×80 μm bottom plate with contacts to a metal 3 (M3) layer, cf. FIG. 10. For simulation of Q and capacitance C, metal 3 to metal 2 vias are added to emulate connection transistors (P02), and metal 4 to metal 3 vias are added to emulate connection to the top plate contact (P01).

FIG. 9B illustrates a top view on an exemplary MIM CAP according to an exemplary embodiment and a corresponding circuit diagram for a part of the MIM CAP having a capacitance C/4 of the capacitance C of the conventional MIM CAP of FIG. 9A.

The MIM CAP may have four parallel 40 μm×40 μm MIM CAPs with contacts to a M3 layer, cf. FIG. 10, that are arranged in a way so that the bottom contacts of the four MIM CAPs form a cross in the middle of the MIM CAPs. Metal 4 lines are added to enhance the bottom plate contacts.

For simulation of Q and capacitance C, metal 3 to metal 2 vias are added to emulate connection transistors (P02), and metal 4 to metal 3 vias are added to emulate connection to the top plate contact (P01).

Other advantageous layout schemes are also possible. Six, eight, or ten MIM CAPs with contacts to a M3 layer may be used that are arranged in a way such that bottom contacts are arranged between each pair of adjacent MIM CAPs of the six, eight, or ten MIM CAPs. In other words, a single MIM CAP having capacitance C may be divided into a plurality of N MIM CAPs such that the sum of the capacitances Cᵢ for each MIM CAP i of the plurality of N MIM CAPs adds up to C. The plurality of N MIM CAPs are then arranged to reduce resistances for at least the bottom contacts. Top and bottom resistances are shown in the circuit diagrams in FIG. 9A, FIG. 9B, and FIG. 10.

FIG. 10 illustrates a cross section of an exemplary MIM CAP according to an exemplary embodiment and a corresponding circuit diagram for a part of the MIM CAP, each part having a capacitance C/4 of the capacitance C of the conventional MIM CAP of FIG. 9A.

The semiconductor device shown in FIG. 10 comprises a MIM CAP integrated within a multi-layer structure. The semiconductor device includes four metal layers, denoted as M1, M2, M3, and M4. Each layer is interconnected to form the overall structure of the MIM CAP.

The MIM CAP is composed of a plurality of N MIM CAPs coupled in parallel. Each MIM CAP includes a top plate and a bottom plate, with a corresponding capacitance Ci. The top plates and the bottom plates are arranged between the M2 and M3 layers. The MIM CAPs are connected through a series of bottom contacts which may be arranged between pairs of directly adjacent MIM CAPs.

FIG. 10 also shows the electrical connections and components associated with the MIM CAP. A resistor Rt is connected in series with the MIM CAP. Another resistor Rb is connected in series with the MIM CAP.

FIG. 11A and FIG. 11B illustrate the performance of the conventional MIM CAP of FIG. 9A (dashed lines) and the performance of the exemplary MIM CAP of FIG. 9B (solid lines) as a function of frequency. As shown in FIG. 11A, with respect to the layout shown in FIG. 9A, the exemplary layout shown in FIG. 9B has a Q which is improved by approximately 24 at 1 GHz, approximately 10 at 3 GHz, and approximately 5.4 at 5 GHz.

FIG. 11A illustrates the relationship between the quality factor Q and the frequency. The quality factor Q is plotted on the vertical axis, ranging from approximately 5.0 to 150.0, while frequency is plotted on the horizontal axis, ranging from approximately 0.5 GHz to 6.5 GHz.

FIG. 11B illustrates the relationship between capacitance (measured in picofarads, pF) and frequency. The capacitance is plotted on the vertical axis, ranging from approximately 10.00 pF to 20.00 pF, while frequency is plotted on the horizontal axis, ranging from approximately 0.5 GHz to 6.5 GHz.

Aspects of this disclosure can be implemented in various electronic devices. Examples of the electronic devices can include, but are not limited to, consumer electronic products, parts of the consumer electronic products such as packaged radio frequency modules, radio frequency filter die, uplink wireless communication devices, wireless communication infrastructure, electronic test equipment, etc. Examples of the electronic devices can include, but are not limited to, a mobile phone such as a smart phone, a wearable computing device such as a smart watch or an ear piece or smart eyeglasses or virtual reality equipment, a telephone, a television, a computer monitor, a computer, a modem, a hand-held computer, a laptop computer, a tablet computer, a microwave, a refrigerator, a vehicle such as a car, a vehicular electronics system such as an automotive electronics system, a robot such as an industrial robot, an Internet of things device, a stereo system, a digital music player, a radio, IoT radios, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including,” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as,” and the like, unless specifically stated otherwise, or otherwise understood within the context as used, is generally intended to convey that certain examples include, while other examples do not include, certain features, elements and/or states. The word “coupled,” as generally used herein, refers to two or more elements that may be either directly coupled, or coupled by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain examples have been described, these examples have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions and changes in the form of the resonators, filters, multiplexer, devices, modules, wireless communication devices, apparatus, methods, and systems described herein may be made without departing from the spirit of the disclosure. For example, while blocks are presented in a given arrangement, alternative examples may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various examples described above can be combined to provide further examples. The accompanying claims and their equivalents are intended to cover such forms or modifications as would fall within the scope and spirit of the disclosure.

1. A semiconductor device comprising a metal-insulator-metal capacitor having a capacitance, the metal-insulator-metal capacitor comprising:
a plurality of N metal-insulator-metal capacitors coupled in parallel, each metal-insulator-metal capacitor of the plurality of N metal-insulator-metal capacitors having a top plate, a bottom plate, and a corresponding capacitance; and
a plurality of bottom contacts, at least one of the plurality of bottom contacts arranged between a pair of directly adjacent metal-insulator-metal capacitors of the plurality of N metal-insulator-metal capacitors.

2. The semiconductor device of claim 1 wherein the bottom plates of at least two metal-insulator-metal capacitors of the plurality of N metal-insulator-metal capacitors are arranged in a first layer of the at least two metal-insulator-metal capacitors.

3. The semiconductor device of claim 1 wherein each bottom plate of each metal-insulator-metal capacitors of the plurality of N metal-insulator-metal capacitors has a rectangular shape.

4. The semiconductor device of claim 1 wherein the plurality of bottom contacts comprise a bottom contact between each pair of directly adjacent metal-insulator-metal capacitors of the plurality of N metal-insulator-metal capacitors.

5. The semiconductor device of claim 1 wherein N is equal to 2, 4, 6, 8, or 10.

6. The semiconductor device of claim 1 wherein each metal-insulator-metal capacitor of the plurality of N metal-insulator-metal capacitors has a same capacitance.

7. The semiconductor device of claim 1 wherein each metal-insulator-metal capacitor of the plurality of N metal-insulator-metal capacitors is arranged between a metal 2 and a metal 3 layer and has a capacitance of 2 fF/μm².

8. An antennaplexer comprising:
a first signal path between an antenna port and a first output port, the first signal path including a first resonator in series with a first metal-insulator-metal capacitor having a capacitance, the first metal-insulator-metal capacitor including a plurality of metal-insulator-metal capacitors coupled in parallel, each metal-insulator-metal capacitor of the plurality of metal-insulator-metal capacitors having a top plate, a bottom plate, and a corresponding capacitance, and a plurality of bottom contacts, at least one of the plurality of bottom contacts arranged between a pair of directly adjacent metal-insulator-metal capacitors of the plurality of metal-insulator-metal capacitors;
a first shunt path connected to the first signal path between the first resonator and the first output port; and
a second signal path between the antenna port and a second output port, the first signal path configured to transmit signals of a first frequency band and the second signal path configured to transmit signals of a second frequency band that differs from the first frequency band.

9. The antennaplexer of claim 8 wherein the first shunt path includes a stacked resonator including a second resonator in series with a third resonator.

10. The antennaplexer of claim 9 wherein the first shunt path further includes a second metal-insulator-metal capacitor in series with the stacked resonator.

11. The antennaplexer of claim 8 wherein the first signal path includes a second resonator between the first shunt path and the first output port.

12. The antennaplexer of claim 8 further comprising a second shunt path connected to the first signal path between a node where the first shunt path connects to the first signal path and the first output port.

13. The antennaplexer of claim 8 wherein the second signal path includes an inductor-capacitor network without a resonator.

14. The antennaplexer of claim 8 wherein the first resonator is an acoustic wave resonator.

15. The antennaplexer of claim 14 wherein the acoustic wave resonator is a temperature compensated surface acoustic wave device.

16. The antennaplexer of claim 8 wherein the second signal path includes a stacked resonator including a second resonator in series with a third resonator.

17. The antennaplexer of claim 16 further comprising a second shunt path connected to the second signal path between the stacked resonator and the second output port.

18. The antennaplexer of claim 17 wherein the second shunt path includes a third resonator in series with an inductor.

19. The antennaplexer of claim 16 further comprising a third shunt path connected to the second signal path between a node where the second shunt path connects to the second signal path and the second output port.

20. A front-end module comprising:
a power amplifier module configured to amplify one or more radio frequency signals; and
an antennaplexer including a first signal path, a shunt path, and a second signal path, the first signal path between an antenna port and a first output port, and including a first resonator in series with a first metal-insulator-metal capacitor having a capacitance, the first metal-insulator-metal capacitor including a plurality of metal-insulator-metal capacitors coupled in parallel, each metal-insulator-metal capacitor of the plurality of metal-insulator-metal capacitors having a top plate, a bottom plate, and a corresponding capacitance, and a plurality of bottom contacts, at least one of the plurality of bottom contacts arranged between a pair of directly adjacent metal-insulator-metal capacitors of the plurality of metal-insulator-metal capacitors, the first output port in communication with the power amplifier module, the shunt path between the first resonator and the first output port, and the second signal path between the antenna port and a second output port, the first signal path configured to transmit signals of a first frequency band and the second signal path configured to transmit signals of a second frequency band.
